(19) United States
(12) Patent Application Publication
(10) Pub. No.: US 2012/0122258 A1
(43) Pub. Date: May 17, 2012

(54) METHOD FOR MANUFACTURING SEMICONDUCTOR LIGHT EMITTING DEVICE

(75) Inventors: Koichi Nitta, Yokohama-shi (JP); Hidetoshi Fujimoto, Kawasaki-shi (JP)

(73) Assignee: KABUSHIKI KAISHA TOSHIBA, Tokyo (JP)

(21) Appl. No.: 13/051,518

(22) Filed: Mar. 18, 2011

(30) Foreign Application Priority Data
Nov. 11, 2010 (JP) P2010-252407

(51) Int. Cl. H01L 33/06

(52) U.S. Cl. 438/47; 257/E33.008

(57) ABSTRACT

One embodiment provides a method for manufacturing a semiconductor light emitting device, including: forming a semiconductor light emitting device wafer, by: forming a plurality of semiconductor layers on a principal surface of a substrate; and forming a P-type semiconductor layer on the semiconductor layers as an uppermost layer; and forming a plurality of surface irregularities on the P-type semiconductor layer, by putting the semiconductor light emitting device wafer into a heat treating furnace; and performing a heat treatment on the semiconductor light emitting device wafer with (i) a mixed gas of hydrogen and ammonia or (ii) a mixed gas of nitrogen and ammonia.

### CROSS-REFERENCE TO RELATED APPLICATION(S)

This application claims priority from Japanese Patent Application No. 2010-252407 filed on Nov. 11, 2010, the entire contents of which are incorporated herein by reference.

### FIELD

Embodiments described herein relate generally to a method for manufacturing a semiconductor light emitting device.

### BACKGROUND

Generally, a semiconductor light emitting device has a light emitting layer thereinside. Light is generated inside the semiconductor light emitting device by the recombination of electrons and holes injected into the light emitting layer. The light generated inside the semiconductor light emitting device is then extracted outside the semiconductor light emitting device. In order to increase the light emission efficiency of the semiconductor light emitting device, it is effective to enhance light extraction efficiency.

In order to enhance the light extraction efficiency, it has been proposed to form uneven surface structures (irregularities) in a P-type contact layer, by forming a metal film on a surface of the P-type contact layer and performing heat treatment thereon. However, the above mentioned method does not have sufficient reproducibility, and a process becomes complex. It has also been proposed to use a photonic crystal. However, in this method, a damaged layer is generated due to surface treatment, and a semiconductor light emitting device is deteriorated. Further, since a high level microfabrication techniques are required, a process becomes complex.

### BRIEF DESCRIPTION OF DRAWINGS

FIG. 1A is a cross-sectional view of a semiconductor wafer according to a first embodiment. FIG. 1B is an enlarged cross-sectional view illustrating a P-type contact layer in a region A in FIG. 1A.

FIG. 2 illustrates a heat treatment sequence according to the first embodiment.

FIG. 3 illustrates atomic force microscope (AFM) surface images of the P-type contact layer according to the first embodiment.

FIG. 4 illustrates the density of irregularities of the P-type contact layer according to the first embodiment.

FIG. 5 illustrates the relationship between the density of irregularities and a root-mean-square (RMS) with respect to heat treatment temperature in the P-type contact layer according to the first embodiment.

FIG. 6 illustrates the relationship among the surface conditions of the P-type contact layer according to the first embodiment with respect to heat treatment time.

FIG. 7 illustrates the relationship among the surface conditions of the P-type contact layer according to the first embodiment with respect to NH₃-gas-flow-rate.

FIG. 8 illustrates light output characteristics according to the first embodiment.

FIG. 9 illustrates a heat treatment sequence according to a second embodiment.

FIG. 10A illustrates AFM surface images of the P-type contact layer according to the second embodiment. FIG. 10B illustrates the density of surface irregularities.

### DETAILED DESCRIPTION

One embodiment provides a method for manufacturing a semiconductor light emitting device, including: forming a semiconductor light emitting device wafer, by: forming a plurality of semiconductor layers on a principal surface of a substrate; and forming a P-type semiconductor layer on the semiconductor layers as an uppermost layer; and forming a plurality of surface irregularities on the P-type semiconductor layer, by putting the semiconductor light emitting device wafer into a heat treating furnace; and performing a heat treatment on the semiconductor light emitting device wafer with (i) a mixed gas of hydrogen and ammonia or (ii) a mixed gas of nitrogen and ammonia.

Hereinafter, embodiments are described with reference to the drawings.

### First Embodiment

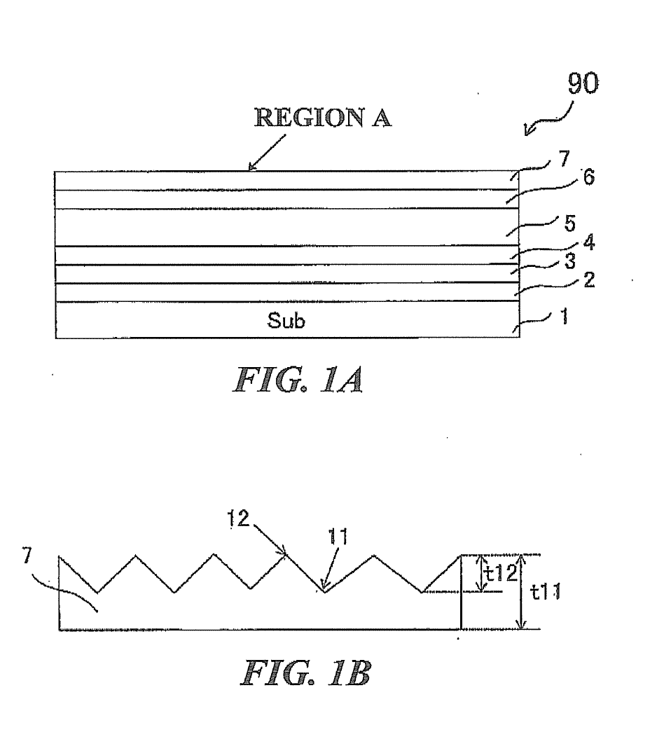

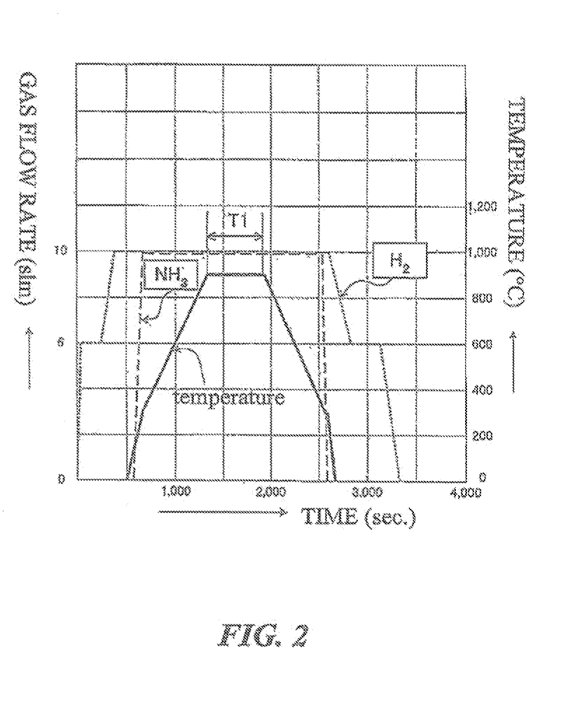

First, a method for manufacturing a semiconductor light emitting device according to a first embodiment is described hereinafter with reference to the drawings. FIGS. 1A and 1B illustrate the cross-sectional structure of a semiconductor wafer according to the first embodiment. FIG. 1A is a cross-sectional view thereof. FIG. 1B is an enlarged cross-sectional view illustrating a P-type contact layer in a region A in FIG. 1A. FIG. 2 illustrates a heat treatment sequence according to the first embodiment. In the present embodiment, to manufacture a light emitting diode (LED), epitaxial layers are stacked on a substrate (sapphire or alumina) using a metal-organic chemical vapor deposition (MOCVD) method. And then, a heat treatment is performed in H₂/NH₃ gas atmosphere to provide micro surface irregularities on the P-type contact layer with high density.

As illustrated in FIG. 1A, in a semiconductor wafer 90, epitaxial layers are continuously stacked on a principal surface (front-surface) of a substrate 1 using a MOCVD method. The epitaxial layers are different from one another in composition, and include a buffer layer 2, an undoped layer 3, an N-type contact layer 4, a multiple quantum well (MQW) light emitting layer 5, a P-type overflow preventing layer 6 and a P-type contact layer 7.

The semiconductor wafer 90 is a semiconductor light emitting device wafer used for manufacturing LEDs. In a wafer process, etching, contact/film-formation, interconnecting and the like are performed on the semiconductor wafer 90 to thereby form semiconductor light emitting devices (LEDs). Then, as a packaging process, the formed LEDs are separated into individual pieces and respectively sealed to be indoor/outdoor indication lamps, automobile headlights and stoplights, road-signs, traffic-signals, small lights and the like.

For example, a sapphire substrate is used as the substrate 1. The buffer layer 2 is formed of an indium gallium aluminum nitride material In(ₓ₁)Ga(_{y1})Al(_{1-x1-y1})N. The undoped layer 3 is formed of an indium gallium aluminum nitride material In(ₓ₂)Ga(_{y2})Al(_{1-x2-y2})N. The N-type contact layer 4 is formed of an indium gallium aluminum nitride material In(ₓ₃)Ga(_{y3})Al(_{1-x3-y3})N. The MQW light emitting layer 5 is formed of an indium gallium aluminum nitride material In(ₓ₄)Ga(_{y4})Al(_{1-x4-y4})N. The P-type overflow preventing layer 6 is formed of an indium gallium aluminum nitride material In(ₓ₅)Ga(_{y5})Al(_{1-x5-y5})N. The P-type contact layer 7 is formed of an indium gallium aluminum nitride material In(ₓ₆)Ga(_{y6})Al(_{1-x6-y6})N. In the MQW light emitting layer 5, plural well layers having thicknesses ranging from 0.1 nm to 100 nm and plural barrier layers which differ in composition (x, y) from the well layers and have thicknesses ranging from 0.1 nm to 100 nm are alternately arranged.

As illustrated in FIG. 1B, a large number of micro surface irregularities are formed on the P-type contact layer 7 of the semiconductor wafer 90. The P-type contact layer 7 has a layer thickness t11, and an irregularity depth t12 which is a depth from a convex 12 to a concave 11 is smaller than the layer thickness t11. The convex 12 and the concave 11 may be collectively referred to as an irregularity (surface irregularity) 11, 12.

As illustrated in FIG. 2, after the epitaxial growth by the MOCVD method, heat treatment is continuously performed in H₂/NH₃ (hydrogen/ammonia) gas atmosphere using a reacting furnace of a MOCVD apparatus. Consequently, a large number of micro surface irregularities are formed on the P-type contact layer 7.

More specifically, first, H₂ (hydrogen) gas is introduced into the reacting furnace of the MOCVD apparatus. After the flow rate of the H₂ (hydrogen) gas reaches a predetermined value, the temperature of the reacting furnace is increased with a predetermined rising rate. When the temperature of the reacting furnace reaches, e.g., 100° C., NH₃ (ammonia) gas is further introduced into the reacting furnace. After the flow rate of the NH₃ (ammonia) gas reaches a predetermined value and the temperature of the reacting furnace reaches a predetermined temperature (e.g., 900° C.) the heat treatment on the semiconductor wafer 90 is continued for an annealing time T1. A crystal growth process can be directly transitioned to a heat treatment process. In this case, the above-mentioned temperature rise process can be deleted, thereby reducing a process time.

Upon completion of the heat treatment, the temperature of the reacting furnace of the MOCVD apparatus is lowered with a predetermined lowering rate. When the temperature of the reacting furnace reaches, e.g., 300° C., the supply of NH₃ (ammonia) gas is stopped. When the temperature of the reacting furnace reaches room temperature, the supply of H₂ (hydrogen) gas is gradually reduced. After the lapse of a predetermined time from then, the supply of H₂ (hydrogen) gas is stopped.

Because the reacting furnace of the MOCVD apparatus is used in this embodiment, it is not necessary to take out the semiconductor wafer 90 outside. Therefore, contamination of the semiconductor wafer 90 in the heat treatment process can be suppressed. In addition, because the MOCVD apparatus can precisely control a heat treatment temperature, a large number of micro surface irregularities can be formed on the P-type contact layer 7 in a well-controlled manner.

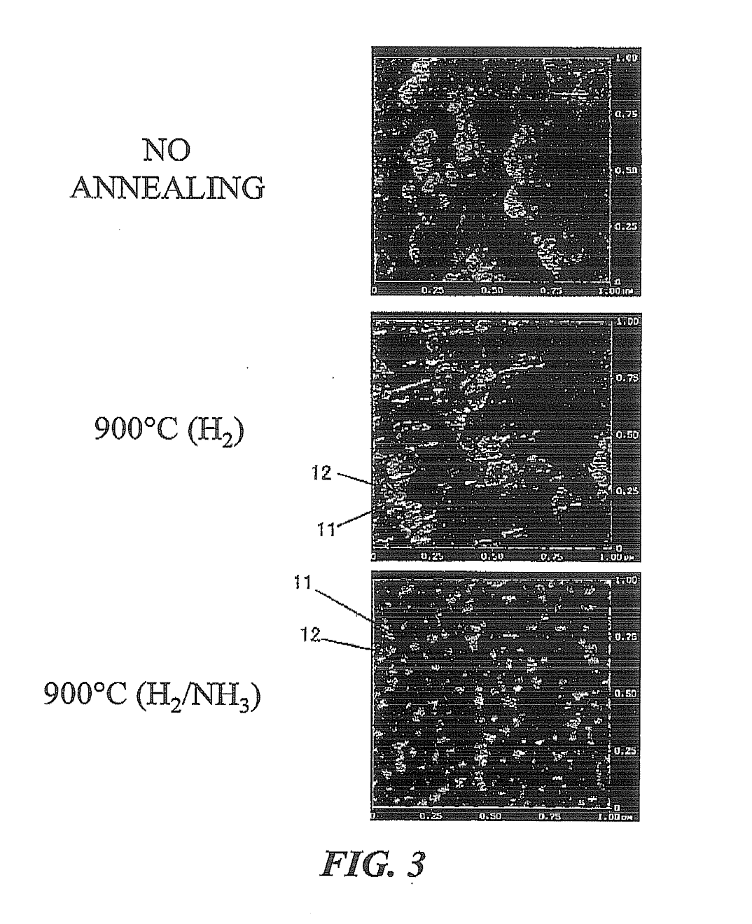

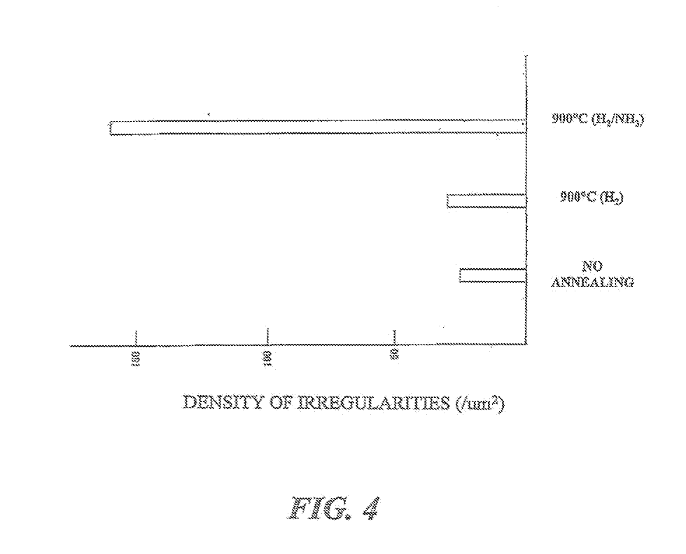

Next, the advantages of the heat treatment of the semiconductor wafer are described with reference to FIGS. 3 to 8. FIG. 3 illustrates AFM surface images of the P-type contact layer 7. FIG. 4 illustrates the density of irregularities of the P-type contact layer 7. Here, the heat treatment is performed at a heat-treatment temperature of 900° C. (incidentally, the heat treatment sequence, the annealing time T1 and the gas flow rate illustrated in FIG. 2 are used). Results of the heat treatment are compared with that in the case of performing no annealing (i.e., no heat treatment).

As shown in FIG. 3, in the semiconductor wafer 90 just after the epitaxial growth in the case of performing no annealing (no heat treatment), the P-type contact layer 7 has a relatively flat surface shape. That is, the density of the surface irregularities 11, 12 (the concave 11 and the convex 12) is small.

In the case of performing the heat treatment at 900° C. in H₂ (hydrogen) gas atmosphere, the density of the surface irregularities 11, 12 of the P-type contact layer 7 slightly increases.

On the other hand, in the case of performing the heat treatment at 900° C. in H₂/NH₃ (hydrogen/ammonia) gas atmosphere, the density of the surface irregularities 11, 12 of the P-type contact layer 7 drastically increases.

More specifically, as illustrated in FIG. 4, in the case of performing the heat treatment at 900° C. in H₂ (hydrogen) gas atmosphere, the density of the irregularities 11, 12 increases to only 1.3 times that in the case of performing no annealing (no heat treatment). On the other hand, in the case of performing the heat treatment at 900° C. in H₂/NH₃ (hydrogen/ammonia) gas atmosphere, the density of the irregularities 11, 12 increases to 6.4 times that in the case of performing no annealing (no heat treatment). That is, the density of the irregularities 11, 12 increases to 5 times that in the case of performing the heat treatment at 900° C. in H₂ (hydrogen) gas atmosphere.

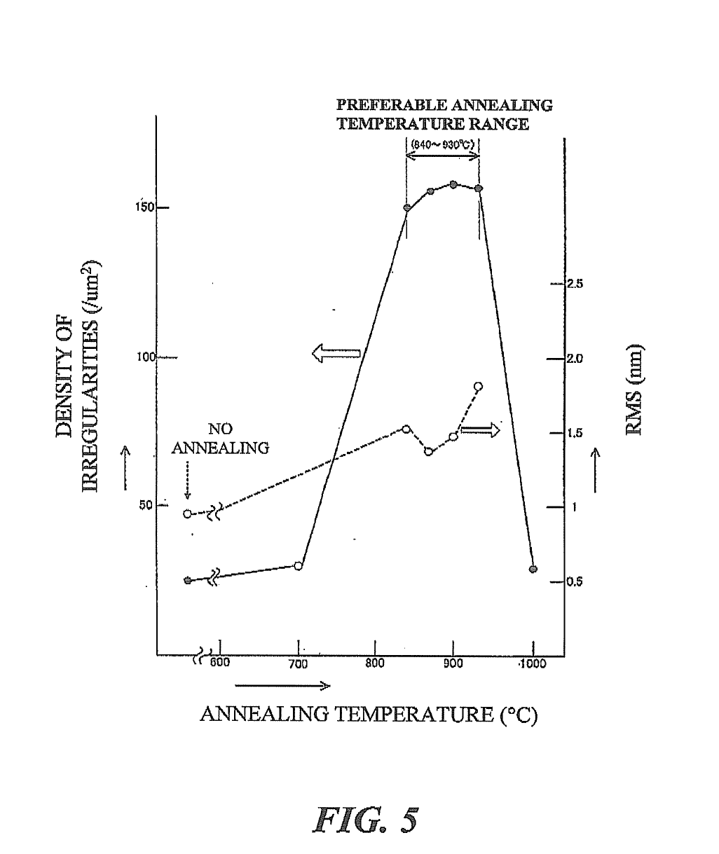

FIG. 5 illustrates the relationship between the density of irregularities and the RMS with respect to heat treatment temperature in the P-type contact layer 7. Here, the heat treatment temperature is changed (incidentally, the heat treatment sequence, the annealing time T1 and the gas flow rate illustrated in FIG. 2 are used). The RMS is an index representing surface roughness.

As illustrated in FIG. 5, in the case of performing heat treatment at 700° C., the density of the surface irregularities of the P-type contact layer slightly increases (to 1.2 times that in the case of performing no annealing (no heat treatment)). Consequently, when the annealing temperature is within a range of temperature equal to or higher than 840° C. and equal to or lower than 930° C., the density of the surface irregularities drastically increases (to 6 through 6.4 times that in the case of performing no annealing (no heat treatment)). In addition, when the heat treatment is performed at 1000° C., the density of the surface irregularities slightly increases (to 1.2 times that in the case of performing no annealing (no heat treatment)).

The RMS value increases (from 1 nm to 1.4 nm through 1.8 nm) by performing heat treatment (at the annealing temperature within a range of temperature equal to or higher than 840° C. and equal to or lower than 930° C.), as compared with the RMS value in the case of performing no annealing (no heat treatment).

As is known from this result, favorable conditions for forming a large number of micro surface irregularities on the P-type contact layer are that the annealing temperature is within a range of temperature equal to or higher than 840° C. and equal to or lower than 930° C. Accordingly, light extraction efficiency can drastically be enhanced by performing heat treatment at the annealing temperature within a range of temperature equal to or higher than 840° C. and equal to or lower than 930° C.

The reason is that NH₃ (ammonia) gas is decomposed into ammonia ions (NH₄⁺ and NH₂⁻), and that then, surface-side elements of a nitride semiconductor are etched by the ammonia ions, so that a large number of irregularities are formed. The etched surface defects of the P-type contact layer are repaired with H₂ (hydrogen) gas, so that a chemically stable surface of the P-type contact layer is formed. At the annealing temperature equal to or lower than 840° C., the rate of decomposition of NH₃ (ammonia) gas is low, thus the surface of the P-type contact layer is not etched. On the other hand, at the annealing temperature equal to or higher than 930° C., NH₃ (ammonia) gas is decomposed into H₂ (hydrogen) gas and N₂ (nitrogen) gas, thus the efficiency of etching the P-type contact layer's surface is significantly deteriorated and the formation of micro irregularities is not accelerated.

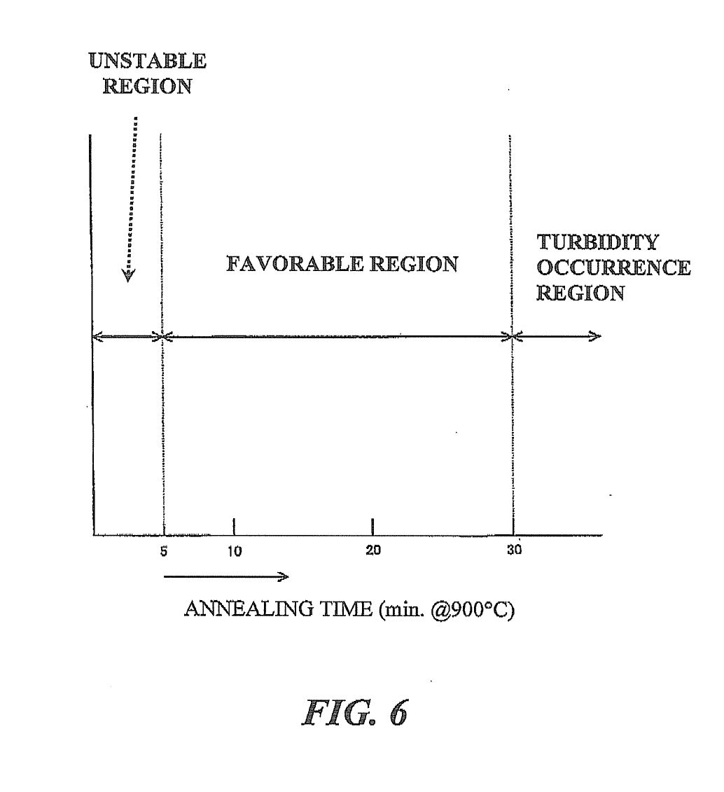

FIG. 6 illustrates the relationship among the surface conditions of the P-type contact layer with respect to heat treatment time. Here, the heat treatment time is changed (the heat treatment sequence and the gas flow rate illustrated in FIG. 2 are used).

As illustrated in FIG. 6, the reaction of the surface of the P-type contact layer is not saturated if the heat treatment time is less than 5 minutes. Thus, there is no reproducibility of micro irregularities in each heat treatment lot, The process is unstable. In a range of the heat treatment time equal to or longer than 5 minutes and equal to or shorter than 30 minutes, the reaction of the surface is saturated. A large number of micro irregularities are stably formed with good reproducibility, and thus, the light extraction efficiency can drastically be enhanced. If the heat treatment time is longer than 30 minutes, the surface shape of the P-type contact layer is greatly changed. In addition, the surface of the P-type contact layer 7 is brought into a turbid state in which light generated in the MQW light emitting layer 5 is scattered and not extracted outside.

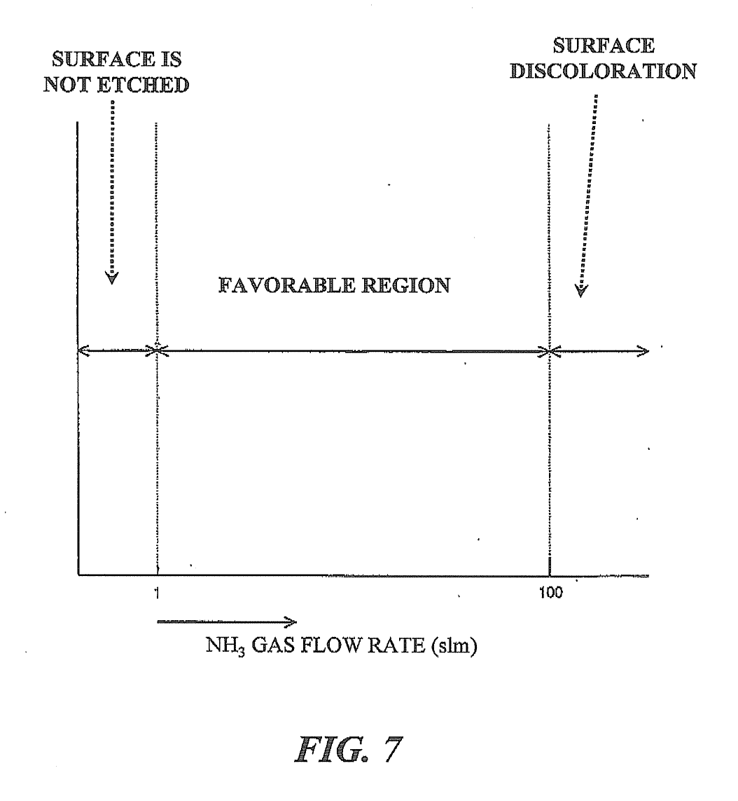

FIG. 7 illustrates the relationship among the surface conditions of the P-type contact layer and NH₃-gas-flow-rate. Here, the flow rate of NH₃ (ammonia) gas is changed (the heat treatment sequence and the annealing time T1 illustrated in FIG. 2 are used).

As illustrated in FIG. 7, if the flow rate of NH₃ (ammonia) gas is less than 1 standard liter/minute (slm), the surface of the P-type contact layer is not etched. In a range of the flow rate of NH₃ (ammonia) gas, which is equal to or higher than 1 slm and equal to or lower than 100 slm, the reaction of the surface is stable and doesn't depend on a heat treatment lot, so that a large number of micro irregularities are stably formed with good reproducibility. Consequently, the light extraction efficiency can dramatically be enhanced. If the flow rate of NH₃ (ammonia) gas is higher than 100 slm, the surface of the P-type contact layer is roughened and discolored. Thus, surface defects thereof are not repaired.

Next, the flow rate of H₂ (hydrogen) gas is described hereinafter. Although unillustrated in the figures, an optimal range of the flow rate of H₂ (hydrogen) gas is such that a ratio of a flow rate of H₂ (hydrogen) gas to a flow rate of NH₃ (ammonia) is equal to or higher than 0.1 and is equal to or less than 10. It is confirmed that in this range, the reaction of the surface is stable and that a large number of micro irregularities are stably formed with good reproducibility, independent of a heat treatment lot.

The above flow rate of NH₃ (ammonia) gas and that of H₂ (hydrogen) gas are not absolute values but relative values. In addition, the flow rates are set correspondingly with the reacting furnace of the above MOCVD apparatus. If the shapes or the like of the reacting furnace or a heat treating furnace of the MOCVD apparatus is changed, the optimal gas flow rate will be changed accordingly.

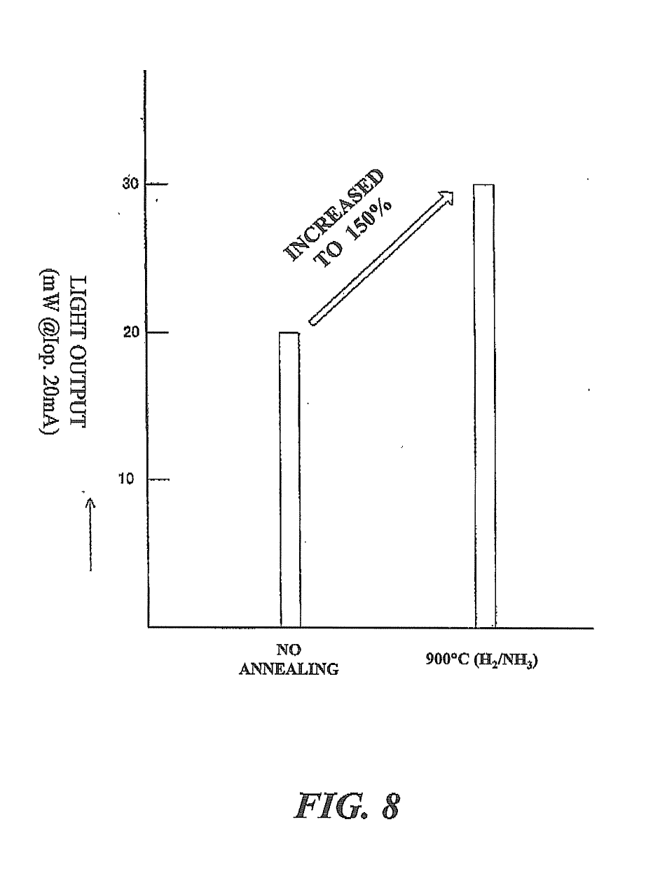

FIG. 8 illustrates light output characteristics of LEDs. Here, an LED obtained by producing light emitting devices in the wafer process from the semiconductor wafer 90 having the P-type contact layer 7 on which a large number of micro surface irregularities are formed, separating the wafer 90 into individual pieces and then sealing the individual pieces is compared with an LED obtained by performing no heat treatment so that a large number of micro surface irregularities are not formed on the P-type contact layer 7.

As illustrated in FIG. 8, the light output of the LED, which is produced without a heat treatment, is 20 mW at an operating current of 20 mA. On the other hand, the light output of the LED, which is obtained by performing the heat treatment at a heat treatment temperature of 900° C. in the H₂/NH₃ (hydrogen/ammonia) gas atmosphere, is 30 mW (1.5 times that of the LED obtained by performing no heat treatment) at an operating current of 20 mA.

Next, a result of a moisture resistance test is described hereinafter. As a result of a moisture resistance test (relative humidity is 90% at a temperature of 90° C.), the LED, which is obtained by performing the heat treatment in the H₂/NH₃ (hydrogen/ammonia) gas atmosphere at a heat treatment temperature of 900° C., maintains 90% or more of the initial value of the light output for 10,000 hours from the start of the test. Thus, as compared with the related-art method, damage caused to the surface of the P-type contact layer 7 is drastically reduced, and a highly-reliable light emitting device can be implemented.

According to the first embodiment, the buffer layer 2, the undoped layer 3, the N-type contact layer 4, the MQW light emitting layer 5, the P-type overflow preventing layer 6 and the P-type contact layer 7 are consecutively stacked on the substrate 1 using the MOCVD method to thereby form the semiconductor wafer 90. And, a large number of micro surface irregularities are formed on the P-type contact layer 7 by performing the heat treatment in the H₂/NH₃ (hydrogen/ammonia) gas atmosphere using the reacting furnace of the MOCVD apparatus after the epitaxial growth according to the MOCVD method.

Accordingly, the light extraction efficiency can be enhanced. Thus, the light emission efficiency can be enhanced. In addition, since the complex process for forming micro surface irregularities on the P-type contact layer can be omitted, the process can be shortened and the damage can be reduced as compared with the related-art method. Consequently, an efficient and reliable semiconductor light emitting device can be provided. According to the present embodiment, the formation of the surface irregularities on the P-type contact layer 7 is performed in the reacting furnace of the MOCVD apparatus. However, type of a furnace is not limited thereto. Any other type of a heat treatment furnace can be used, as long as, e.g., NH₃ (ammonia) gas and H₂ (hydrogen) gas can be introduced thereinto.

### Second Embodiment

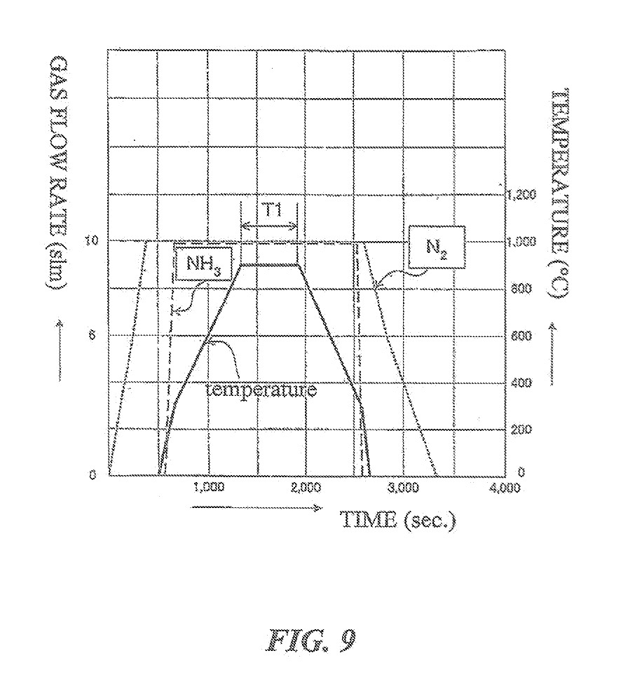

Next, a method for manufacturing a semiconductor light emitting device according to a second embodiment is described hereinafter with reference to the drawings. FIG. 9 illustrates a heat treatment sequence according to the present embodiment. In the present embodiment, to manufacture an LED, epitaxial layers are stacked on a substrate (sapphire or alumina) using the MOCVD method. And then, a heat treatment is performed in N₂/NH₃ gas atmosphere to provide micro surface irregularities on the P-type contact layer with high density.

As illustrated in FIG. 9, after the epitaxial growth according to the MOCVD method, the heat treatment is continuously performed in the N₂/NH₃ gas atmosphere using the reacting furnace of the MOCVD apparatus. Thus, a large number of micro surface irregularities are formed on the P-type contact layer 7 of the semiconductor wafer 90.

More specifically, first, N₂ (nitrogen) gas is introduced into the reacting furnace of the MOCVD apparatus. After the flow rate of the N₂ (nitrogen) gas reaches a predetermined value, the temperature of the reacting furnace is increased with a predetermined rising rate. When the temperature of the reacting furnace reaches, e.g., 100° C., NH₃ (ammonia) gas is further introduced into the reacting furnace. After the flow rate of the NH₃ (ammonia) gas reaches a predetermined value and the temperature of the reacting furnace reaches a predetermined temperature (e.g., 900° C.), the heat treatment on the semiconductor wafer 90 is continued for an annealing time T1.

Upon completion of the heat treatment, the temperature of the reacting furnace of the MOCVD apparatus is lowered with a predetermined lowering rate. When the temperature of the reacting furnace reaches, e.g., 300° C., the supply of the NH₃ (ammonia) gas is stopped. When the temperature of the reacting furnace reaches room temperature, the supply of N₂ (nitrogen) is gradually reduced. After a lapse of a predetermined time from then, the supply of N₂ (nitrogen) is stopped.

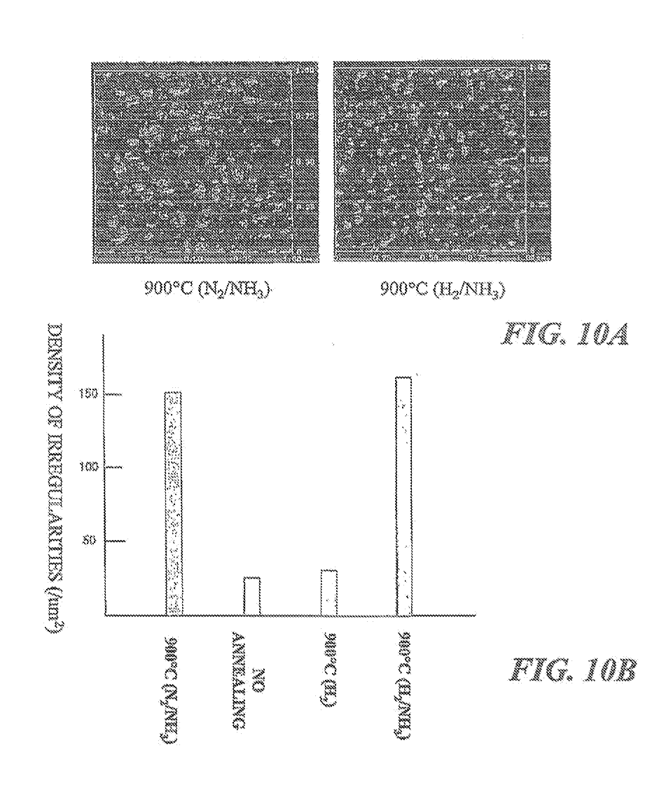

Next, the advantages of the heat treatment performed on the semiconductor wafer are described hereinafter with reference to FIGS. 10A and 10B. FIGS. 10A and 10B illustrate the surface of the P-type contact layer according to the present embodiment. FIG. 10A illustrates AFM surface images. FIG. 10B illustrates the density of surface irregularities. Here, the heat treatment is performed at a heat treatment temperature of 900° C. (incidentally, the heat treatment sequence, and the annealing time T1 illustrated in FIG. 9 are employed). The density of surface irregularities in the case of performing the heat treatment on such conditions is compared with that in the case of performing no annealing (i.e., no heat treatment).

As illustrated in FIG. 10A, the density of the surface irregularities 11, 12 (the concave 11 and the convex 12) of the P-type contact layer 7 in the case of performing the heat treatment at a heat treatment temperature of 900° C. in N₂/NH₃ (nitrogen/ammonia) gas atmosphere increases drastically, similarly to the case of performing the heat treatment at a heat treatment temperature of 900° C. in H₂/NH₃ (hydrogen/ammonia) gas atmosphere according to the first embodiment.

More specifically, as illustrated in FIG. 10B, the density of irregularities in the case of performing the heat treatment at a heat treatment temperature of 900° C. in N₂/NH₃ (nitrogen/ammonia) gas atmosphere increases to six times that in the case of performing no annealing (i.e., no heat treatment) (and increases to 4.7 times that in the case of performing the heat treatment at a heat treatment temperature of 900° C. in the H₂ (hydrogen) gas atmosphere).

It is confirmed that LEDs produced by performing the heat treatment at a heat treatment temperature of 900° C. in N₂/NH₃ (nitrogen/ammonia) gas atmosphere have a high reliability and a high light extraction efficiency, similarly to the LEDs produced by performing the heat treatment at a heat treatment temperature of 900° C. in the H₂/NH₃ (hydrogen/ammonia) gas atmosphere according to the first embodiment.

Preferably, in the second embodiment, each of the heat treatment temperature, the heat treatment time, the flow rate of the NH₃ (ammonia) gas, and the flow rate of the N₂ (nitrogen) gas is set in a range similar to the range according to the first embodiment.

According to the second embodiment, the buffer layer 2, the undoped layer 3, the N-type contact layer 4, the MQW light emitting layer 5, the P-type overflow preventing layer 6, and the P-type contact layer 7 are consecutively stacked on the substrate 1 using the MOCVD method to thereby form the semiconductor wafer 90. And, a large number of micro surface irregularities are formed on the P-type contact layer 7 by performing the heat treatment in the N₂/NH₃ (nitrogen/ammonia) gas atmosphere using the reacting furnace of the MOCVD apparatus after the epitaxial growth according to the MOCVD method.

Accordingly, the light extraction efficiency can be enhanced, and the light emission efficiency can be enhanced. In addition, since the complex process for forming micro surface irregularities on the P-type contact layer can be omitted, the process can be shortened and the damage can be reduced as compared with the related-art method. Consequently, an efficient and reliable semiconductor light emitting device can be provided. Incidentally, according to the embodiments, the epitaxial layers formed of indium gallium aluminum nitride materials InGaAlN differing composition from one another are used as the buffer layer 2, the undoped layer 3, the N-type contact layer 4, the MQW light emitting layer 5, the P-type overflow preventing layer 6 and the P-type contact layer 7. However, these layers a are not limited thereto. For example, GaN layers can be used as the buffer layer 2 and the undoped layer 3. An N-type GaN layers can be used as the N-type contact layer 4, A P-type AlGaN layer can be used as the P-type overflow preventing layer 6. A P-type GaN layer can be used as the P-type contact layer 7.

Although several embodiments have been described above, the embodiments are presented only for illustrative purposes and not intended to limit the scope of the invention. These embodiments can be implemented in other various forms. Various types of omission, substitution, and alteration can be made without departing from the spirit and scope of the invention. Such embodiment and modifications are included within the spirit and scope of the invention and within the scope of claims and equivalents thereof.

1. A method for manufacturing a semiconductor light emitting device, comprising:
forming a semiconductor light emitting device wafer, by;
forming a plurality of semiconductor layers on a principal surface of a substrate; and
forming a P-type semiconductor layer on the semiconductor layers as an uppermost layer; and
forming a plurality of surface irregularities on the P-type semiconductor layer, by
putting the semiconductor light emitting device wafer into a heat treating furnace; and
performing a heat treatment on the semiconductor light emitting device wafer with (i) a mixed gas of hydrogen and ammonia or (ii) a mixed gas of nitrogen and ammonia.

2. The method of claim 1,
wherein the heat treatment is performed within a range of temperature equal to or higher than 840° C. and equal to or lower than 930° C.

3. The method of claim 1,
wherein the heat treatment is performed within a range of time equal to or longer than 5 minutes and equal to or lower than 30 minutes.

4. The method of claim 1,
wherein a depth of the surface irregularities is less than a thickness of the P-type semiconductor layer.

5. The method of claim 1,
a ratio of a flow rate of hydrogen or nitrogen to a flow rate of ammonia is equal to or higher than 0.1 and equal to or less than 10.

6. The method of claim 1,
wherein forming the surface irregularities includes:
supplying a hydrogen gas or a nitrogen gas;
supplying an ammonia gas while heating the heat treating furnace toward a predetermined temperature;
after reaching the predetermined temperature, performing the heat treatment for a predetermined time; and
stopping a supply of the ammonia gas while cooling the heat treating furnace; and
stopping a supply of the hydrogen gas or the nitrogen gas.

7. The method of claim 1,
wherein the substrate is formed of sapphire or alumina.

8. The method of claim 1,
wherein the P-type semiconductor layer and the semiconductor layers are respectively formed of indium gallium aluminum nitride which are different from one another in a composition.

9. The method of claim 1,
wherein each of the P-type semiconductor layer and the semiconductor layers is formed of gallium nitride or of aluminum gallium nitride

10. A method for manufacturing a semiconductor light emitting device, comprising:
forming, within a reaction furnace, a semiconductor light emitting device wafer, by:
preparing a substrate;
forming a plurality of semiconductor layers on a principal surface of the substrate; and
forming a P-type semiconductor layer on the semiconductor layers as an uppermost layer; and
forming a plurality of surface irregularities on the P-type semiconductor layer, by
keeping the semiconductor light emitting device wafer within the reaction furnace; and
performing a heat treatment on the semiconductor light emitting device wafer with (i) a mixed gas of hydrogen and ammonia or (ii) a mixed gas of nitrogen and ammonia.

11. The method of claim 9,
wherein the heat treatment is performed within a range of temperature equal to or higher than 840° C. and equal to or lower than 930° C.

12. The method of claim 9,
wherein the heat treatment is performed within a range of time equal to or longer than 5 minutes and equal to or lower than 30 minutes.

13. The method of claim 9,
wherein a depth of the surface irregularities is less than a thickness of the P-type semiconductor layer.

14. The method of claim 9,
a ratio of a flow rate of hydrogen or nitrogen to a flow rate of ammonia is equal to or higher than 0.1 and equal to or less than 10.

15. The method of claim 9,
wherein forming the surface irregularities includes:
supplying a hydrogen gas or a nitrogen gas;
supplying an ammonia gas while heating the reaction furnace toward a predetermined temperature;
after reaching the predetermined temperature, performing the heat treatment for a predetermined time; and
stopping a supply of the ammonia gas while cooling the reaction furnace; and
stopping a supply of the hydrogen gas or the nitrogen gas.

16. The method of claim 9,
wherein the substrate is formed of sapphire or alumina.

17. The method of claim 9,
wherein the P-type semiconductor layer and the semiconductor layers are respectively formed of indium gallium aluminum nitride which are different from one another in a composition.

18. The method of claim 9,
wherein each of the P-type semiconductor layer and the semiconductor layers is formed of gallium nitride or of aluminum gallium nitride.
